(19) United States
(12) Patent Application Publication
(10) Pub. No.: US 2026/0033370 A1
(43) Pub. Date: Jan. 29, 2026

(54) SYSTEMS AND METHODS FOR REDUCING TRACE EXPOSURE IN STACKED SEMICONDUCTOR DEVICES

(71) Applicant: Micron Technology, Inc., Boise, ID (US)

(72) Inventors: Seng Kim Ye, Singapore (SG); Kelvin Tan Aik Boo, Singapore (SG); Hong Wan Ng, Singapore (SG); Chin Hui Chong, Singapore (SG)

(21) Appl. No.: 19/275,913

(22) Filed: Jul. 21, 2025

Related U.S. Application Data
(60) Provisional application No. 63/674,650, filed on Jul. 23, 2024.

(51) Int. Cl. H01L 23/13; H01L 21/48; H01L 21/56; H01L 21/66; H01L 23/00; H01L 25/065

(52) U.S. Cl. CPC H01L 23/13; H01L 21/4803; H01L 21/4846; H01L 21/565; H01L 25/0657; H01L 22/14; H01L 24/04; H01L 24/05; H01L 24/06; H01L 24/48; H01L 24/96; H01L 24/97; H01L 2224/04042; H01L 2224/05553; H01L 2224/06131; H01L 2224/48147; H01L 2224/48229; H01L 2224/96; H01L 2224/97; H01L 2225/06506; H01L 2225/0651; H01L 2225/06562

(57) ABSTRACT

Stacked semiconductor packages with features to mitigate trace exposer and associated systems and methods are disclosed herein. In some embodiments, the stacked semiconductor package includes a base substrate, a stack of dies carried by the base substrate, and a mold material deposited at least partially encapsulating the stack of dies. The base substrate can include an active surface and a back surface opposite the active surface. Further, the active surface can include one or more cuts into a peripheral portion of the active surface (e.g., stepped structures at the peripheral edges of the base substrate). The base substrate can also include a plurality of bond pads carried by the active surface over the peripheral portion. Still further, the mold material can fill each of the one or more cuts in the active surface, thereby insulating the bond pads from exposure at a sidewall of the stacked semiconductor package.

### CROSS-REFERENCE TO RELATED APPLICATION(S)

The present application claims priority to U.S. Provisional Patent Application No. 63/674,650, filed Jul. 23, 2024, the disclosure of which is incorporated herein by reference in its entirety.

### TECHNICAL FIELD

The present technology is generally directed to systems and methods for forming stacked semiconductor devices and more specifically to systems and methods for creating stepped structures to remove plating lines from stacked semiconductor devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or failure detectability.

### BRIEF DESCRIPTION OF THE DRAWINGS

FIG. 1A is a partially schematic cross-sectional view of a stacked semiconductor device configured in accordance with embodiments of the present technology.

FIG. 1B is a partially schematic side view of a stacked semiconductor device configured in accordance with embodiments of the present technology.

FIG. 1C is a partially schematic top view of a stacked semiconductor device configured in accordance with embodiments of the present technology.

FIG. 2 is a flow diagram of a process for manufacturing a stacked semiconductor device in accordance with embodiments of the present technology.

FIGS. 3A-3D are partially schematic top views of a bulk interposer at various stages of manufacturing in accordance with embodiments of the present technology.

FIG. 4 is a partially schematic cross-sectional view of an interposer configured in accordance with embodiments of the present technology.

FIG. 5 is a schematic view of a system that includes stacked semiconductor devices configured in accordance with embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

As discussed in more detail below, the present disclosure is directed to systems and methods for reducing (or eliminating) the exposure of conductive structures (e.g., copper traces) at the sidewalls of stacked semiconductor devices. For example, the methods disclosed herein include forming one or more cuts in an interposer substrate that each passes through conductive traces and/or pads (e.g., bond fingers) at the periphery of individual packages in the interposer. When the interposer (and semiconductor components stacked thereon, such as semiconductor dies) are encased with a molding compound, the molding compound can flow into the cuts in the interposer substrate. As a result, when the individual packages are singulated, the portion of the molding material in the cuts spaces the conductive structures apart from an outer sidewall of the individual packages. That is, the portion of the molding material in the cuts insulates the conductive structures from exposure at the sidewalls of the individual packages. As discussed in more detail below, the insulation can help reduce metal migration, corrosion, and/or other deleterious effects at the sidewalls of the semiconductor packages. Additionally, or alternatively, the cuts and mold filling can help reduce the space needed between a bond finger edge and a package edge to avoid exposing the conductive features.

As used herein, the terms “vertical,” “lateral,” “upper,” “lower,” “top,” and “bottom” can refer to relative directions or positions of features in the semiconductor components (e.g., substrates, dies, and/or the like) in view of the orientation shown in the drawings. For example, “bottom” can refer to a feature positioned closer to the bottom of a page than another feature. These terms, however, should be construed broadly to include semiconductor components having other orientations, such as inverted or inclined orientations where top/bottom, over/under, above/below, up/down and left/right can be interchanged depending on the orientation.

Further, although primarily discussed herein in the context of stacking dies on a prepreg substrate, one of skill in the art will understand that the scope of the invention is not so limited. For example, the methods disclosed herein can also be used to form stepped structures in silicon interposers to reduce (or eliminate) conductive exposure at the sidewalls of high-bandwidth memory (HBM) devices (e.g., 2.5D HBM devices and/or 3D HBM devices). Accordingly, the scope of the invention is not confined to any subset of embodiments, and is confined only by the limitations set out in the appended claims.

Still further, unless the context indicates otherwise, structures disclosed herein can be formed using one or more semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Smaller footprints, increased density, and increased lifespans are features that are demanded in stacked semiconductor devices. To meet these demands, a base substrate (e.g., printed circuit boards, other prepreg substrates, silicon substrates, and/or the like) can be manufactured with a variety of metallization structures (e.g., external-facing bond pads, route lines and other metallization layers, internal bond pads and bond fingers, and/or the like). A plurality of semiconductor dies (e.g., memory dies, logic dies, controller dies, and/or the like) can then be stacked on the base substrate (sometimes also referred to herein as an “interposer”) and connected to the base substrate via wire bonds, through substrate vias (TSVs), and/or the like). The stack allows the semiconductor device to include additional memory, functionality, processing power, and/or the like into the same longitudinal footprint.

The stacked semiconductor devices are typically manufactured in bulk, for example at a wafer and/or interposer level. That is, multiple stacked semiconductor devices can be manufactured on a single interposer, and then singulated from each other to isolate individual devices. During bulk manufacturing, it can be valuable to couple various metallization structures in the base substrate to an interposer bus that provides access (e.g., a communicative link) to the metallization structures and/or the semiconductor dies (“stacked dies”) stacked over the base substrate. In particular, the metallization structures often include bond fingers that are electrically coupled to the stacked dies (e.g., via wire bonds, traces and TSVs, and/or the like) and electrically coupled to the interposer bus (e.g., via traces).

However, when the stacked semiconductor devices are singulated, a portion of the bond fingers (and/or the traces coupled to the bond fingers) are exposed at the sidewall of the stacked semiconductor device. The metal (e.g., copper, gold, and/or the like) in the exposed portions of the bond fingers and/or traces, in turn, has deleterious effects on the resulting package. For example, exposed metal can migrate through electrochemical migration to create shorts, destroy traces and/or other electrical connections, and/or the like. In another example, the exposed metal provides an opening for corrosion in the stacked semiconductor device that can undermine the operation of and/or reduce the lifetime of the stacked semiconductor device. Still further, when the stacked semiconductor devices are attached to another substrate (e.g., a printed circuit board), the exposed metal is at risk of contacting the exposed metal in an adjacent device, thereby creating shorts between adjacent devices. To address those deleterious effects, stacked semiconductor devices often include etch-back openings at the package edge that create windows at the package edge avoid shorts. However, the etch-back openings require that the stacked semiconductor devices include traces extending beyond the bond fingers to cut into, which can be costly and/or require additional longitudinal footprint space for each of the stacked semiconductor devices. Further, the etch-back openings do not address the problems associated with exposed metal at the sidewall, which remains within the windows of the etch-back openings. As an alternative, some stacked semiconductor devices include superfluous traces extending beyond the bond fingers to create a metal barrier that can migrate and/or corrode without disrupting the bond fingers. However, the superfluous trace also requires additional longitudinal footprint space for each of the stacked semiconductor devices and only temporarily addresses the deleterious effects of the exposed metal.

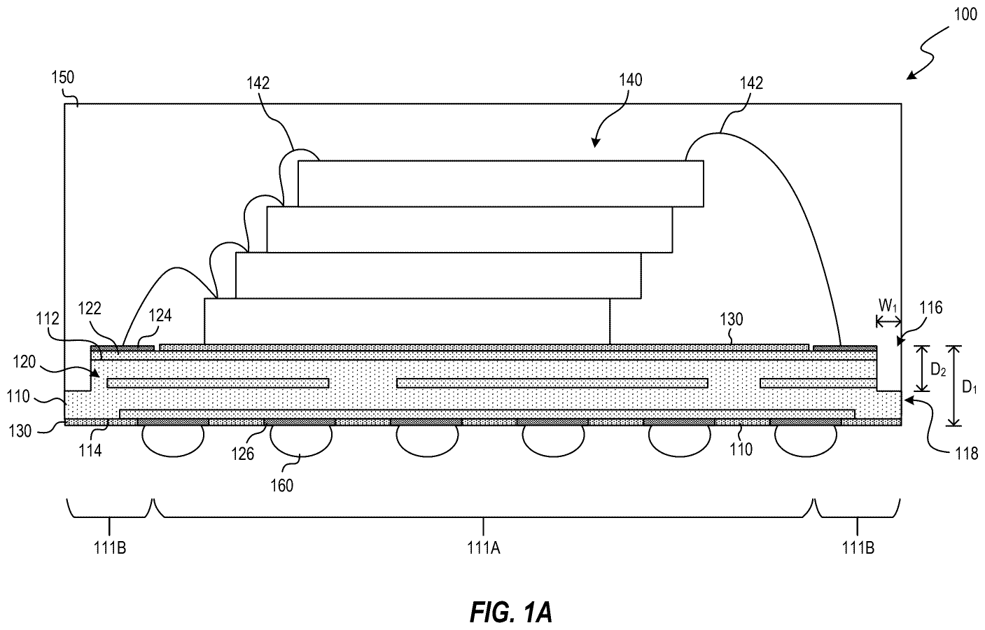

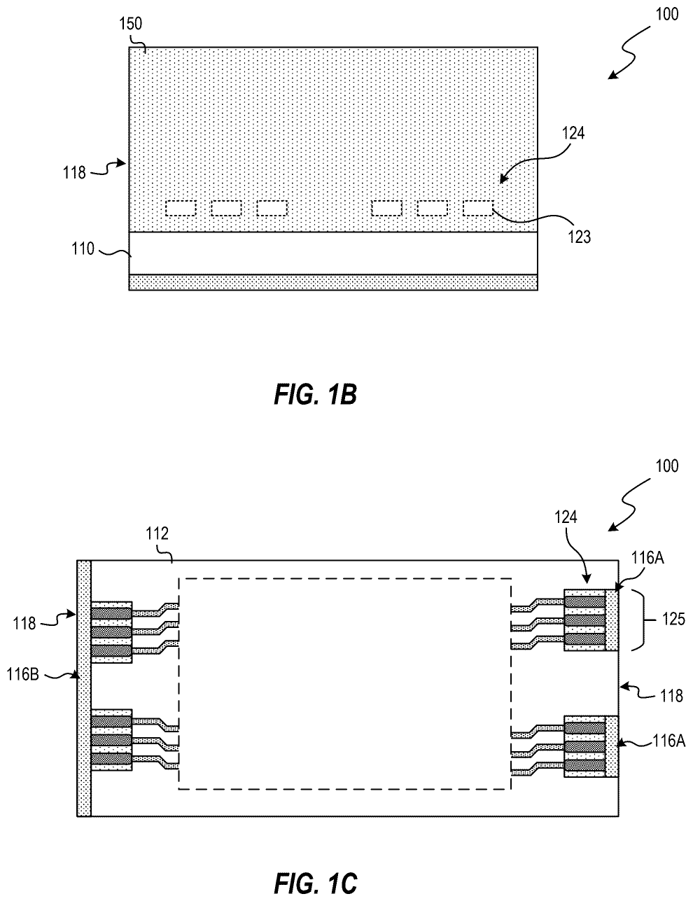

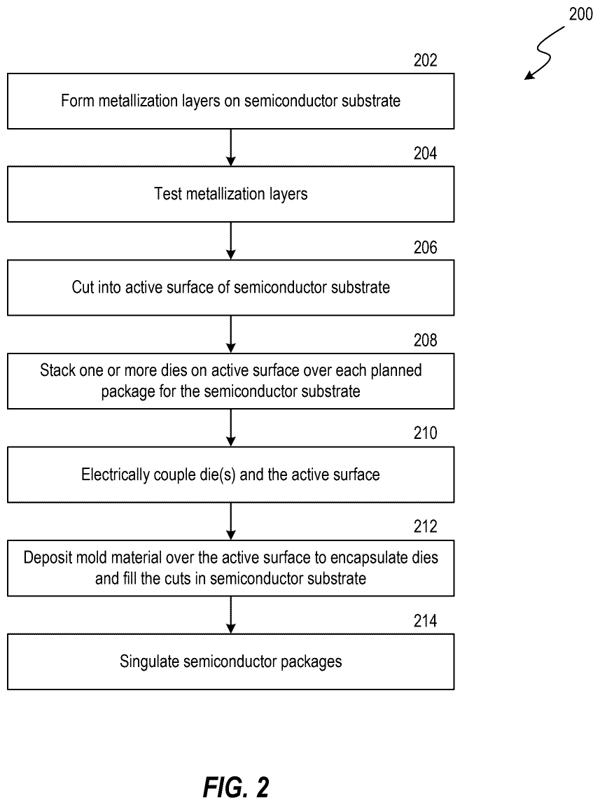

The systems and methods disclosed herein address the problems discussed above by forming one or more cuts in the active surface of the base substrate during manufacturing. The cut(s) can each intersect one or more of the bond fingers along a planned peripheral edge for the stacked semiconductor devices (e.g., corresponding to a singulation line). As a result, the cut(s) create a gap between the conductive material in the bond fingers and the planned peripheral edge. The stacked semiconductor devices can then be encapsulated by a molding material that at least partially fills each of the cut(s). As a result, when the stacked semiconductor dies are singulated along the planned peripheral edges, the mold material filling the cut(s) is positioned between the conductive material in the bond fingers and the sidewall of the resulting semiconductor package. Said another way, the mold material in the cut(s) reduces (or eliminates) the amount of conductive material exposed at the sidewalls of the stacked semiconductor device, in turn reducing (or eliminating) the chance that the conductive material will migrate and/or corrode. Further, the cut(s) (and mold material filling the cut(s)) do not require additional space in the longitudinal footprint for the stacked semiconductor devices. Accordingly, the cut(s) can help address the problems discussed above without impeding demands for reductions in the footprints of stacked semiconductor devices. Additional details on the process of forming the cuts, as well as the resulting interposers and stacked semiconductor devices, are discussed in more detail below with reference to FIGS. 1A-5.

FIGS. 1A-1C are partially schematic views of a stacked semiconductor device 100 configured in accordance with embodiments of the present technology. As illustrated in FIG. 1A, the stacked semiconductor device 100 (sometimes also referred to herein as a “semiconductor package”) includes a base substrate 110 that includes a central portion 111A and a peripheral portion 111B surrounding the central portion 111A. Further, the base substrate 110 (sometimes also referred to herein as a “core substrate”) and has a front surface 112 (sometimes also referred to herein as an “active surface,” a “top surface,” and/or the like) and a back surface 114 (sometimes referred to herein as a “bottom surface,” an “external connection surface,” a “rear surface,” and/or the like) opposite the front surface 112. The base substrate 110 can include any suitable semiconductor material, such as a prepreg substrate, silicon, various other organic materials, and/or various suitable inorganic materials. Further, as illustrated in FIG. 1A, the base substrate 110 can include various metallization structures 120 formed thereon, such as route lines, traces, TSVs, bond pads, bond sites, and/or the like. For example, in the illustrated embodiment, the metallization structures 120 include metallization layers 122 (e.g., metal route lines, traces, and/or the like) formed throughout the base substrate 110; bond fingers 124 (e.g., clusters of one or more bond pads, bond sites, and/or other suitable bonding structures) formed on the front surface 112 in the peripheral portion 111B of the base substrate 110; and external package bond sites 126 formed on the back surface 114 in the central portion 111A (sometimes referred to herein as a “die-stacking areas”) of the base substrate 110.

As further illustrated in FIG. 1A, the stacked semiconductor device 100 can include a dielectric layer 130 formed around the base substrate 110, a stack 140 of one or more semiconductor dies stacked on the front surface 112 in the central portion 111A, a mold material 150 at least partially encapsulating the stack 140 and the front surface 112, and external package connections 160 (e.g., solder structures and/or other suitable bonding structures) coupled to the external package bond sites 126. The dielectric layer can be formed on both the front surface 112 and the rear surface 114 of the base substrate 110. Further, the dielectric layer 130 can be formed on around the metallization structures 120 with openings for the bond fingers 124, the external package bond sites 126, and/or any other suitable structures. Accordingly, the dielectric layer 130 can insulate and/or protect the base substrate 110 and/or various components of the metallization structures 120.

The stack 140 can include any suitable number of semiconductor dies (e.g., one two, three, four, eight, sixteen, thirty-two, and/or any other suitable number). Further, the stack 140 can include any suitable type and/or combination of semiconductor dies, such as one or more memory and/or dies (e.g., DRAM dies, NAND dies, and/or the like), one or more logic dies, one or more controller dies, one or more processing dies, and/or any other dies. In the illustrated embodiment, the dies in the stack 140 are offset from each other and are each coupled to the bond fingers 124 at the front surface 112 through one or more wire bonds 142. In some embodiments, the dies in the stack 140 are coupled to the bond fingers 124 through one or more TSVs and/or route lines. In some embodiments, the stack 140 includes multiple substacks that are laterally offset in different directions. For example, the stack 140 can include a first substack generally similar to the dies illustrated in FIG. 1A and a second substack carried by the first substack and generally mirrored with respect to the dies illustrated in FIG. 1A.

As further illustrated in FIG. 1A, the front surface 112 of the base substrate 110 can include one or more cuts 116 (two illustrated in the cross-sectional view of FIG. 1A) at a peripheralmost edge 118 of the base substrate 110. The cuts 116 are adjacent to and/or about the bond fingers 124. Further, the cuts 116 extend to an intermediate depth in the base substrate 110, thereby creating a stepped structure in a sidewall of the base substrate 110. For example, the base substrate 110 can have a first depth D₁ while the cuts 116 have a second depth D₂ that is smaller than the first depth D₁. As discussed in more detail below, the stepped structure of the cuts 116 can be formed by a variety of processes. For example, a manufacturing process can expose the front surface of a bulk interposer to a laser, a saw (e.g., a portion of a dicing saw), a liquid jet, and/or the like to form cavities in the front surface corresponding to the cuts 116. The cavities can abut and/or intersect the bond fingers 124 on a singulation line in the bulk interposer such that the singulation runs at least partially through the cavities. As a result, the cuts 116 can have a first width W₁ that is equal to or less than the width of the cavities. In various embodiments, the first width W₁ can be between about 100 micrometers (μm) and about 50 μm, between about 50 μm and about 10 μm, and/or about 25 μm. As a result, the distance between the bond fingers 124 and the peripherlmost edge of the peripheral portion 111B (sometimes referred to as the “bond finger edge to package edge”) can be reduced as compared to stacked semiconductor devices that rely on etch-back openings and/or a superfluous trace. In turn, the reduced distance can allow the stacked semiconductor device 100 to have a smaller longitudinal footprint than stacked semiconductor devices that rely on etch-back openings and/or a superfluous trace.

The stepped structure formed by the cuts 116 allows a portion of the mold material 150 to be positioned between individual bond pads 123 grouped into the bond fingers 124 and the sidewall of the base substrate 110 (e.g., the peripheralmost edge 118 of the peripheral portion 111B). For example, as best illustrated in FIG. 1B, the portion of the mold material 150 formed over the cuts 116 can insulate each of the bond pads 123 (sometimes also referred to herein as “bonding structures,” “bond sites,” and/or the like) in the bond fingers 124 from exposure to the air at the sidewalls. In turn, the insulation can help reduce (or prevent) the chance that the bond fingers 124 will creep during various packaging processes and/or during the operation of a semiconductor device that includes the stacked semiconductor device 100. Additionally, or alternatively, the insulation can help reduce (or prevent) the chance that the bond fingers 124 will corrode. Said another way, the cuts 116 (and the mold material 150 formed thereon) can help mitigate (or eliminate) the problems associated with conductive material exposed at the sidewalls of the base substrate 110 after singulation. As a result, the cuts 116 (and the mold material 150 formed thereon) can help extend a lifetime of the stacked semiconductor device 100.

As best illustrated in FIG. 1C, in various embodiments, the cuts 116 can extend along the peripheralmost edge 118 for different lengths. For example, as illustrated on the right side of the stacked semiconductor device 100, the bond fingers 124 can each have a footprint 125 with a length that extends along only a portion of the peripheralmost edge 118, and the stacked semiconductor device 100 can include first cuts 116A that extend along the peripheralmost edge 118 only adjacent to the footprint 125. Said another way, the first cuts 116A each have a length that is generally equal to an edge length of the bond fingers along the peripheralmost edge 118 corresponding to the footprint. Because the length of the first cuts 116A is relatively short, the first cuts 116A can require relatively little additional processing time at the bulk interposer stage and/or can require relatively little additional costs. In another example, as illustrated on the left side of the stacked semiconductor device 100, the stacked semiconductor device 100 can include a second cut 116B that extends along an entire side of the peripheralmost edge 118. As a result, the second cut 116B can help eliminate any other metallization structures along the peripheralmost edge 118 on the left side of the stacked semiconductor device 100 (e.g., route lines, other bonding structures, and/or the like) and/or can omit any alignment process while forming the second cut 116B. In various other embodiments, the cuts 116 can extend along any other suitable length of the peripheralmost edge 118. Additionally, it will be understood that the cuts are not limited to only the left and right sides of the stacked semiconductor device 100 and can instead be formed along any suitable portion of the peripheralmost edge 118.

Similarly, referring to FIGS. 1A and 1C in conjunction, the depth and/or width of the cuts 116 can vary between different cuts 116. Purely by way of example, a first cut can have the second depth D₂ illustrated in FIG. 1A while a second cut can have a third depth that reaches an internal metallization layer (e.g., routing layer) to create a space between the internal metallization layer and the peripheralmost edge 118. In another example, the first cuts 116A illustrated in FIG. 1B can have a different width from the second cut 116B (e.g., based on variances in the singulation process, planned differences and/or different locations of the bond fingers 124, and/or the like).

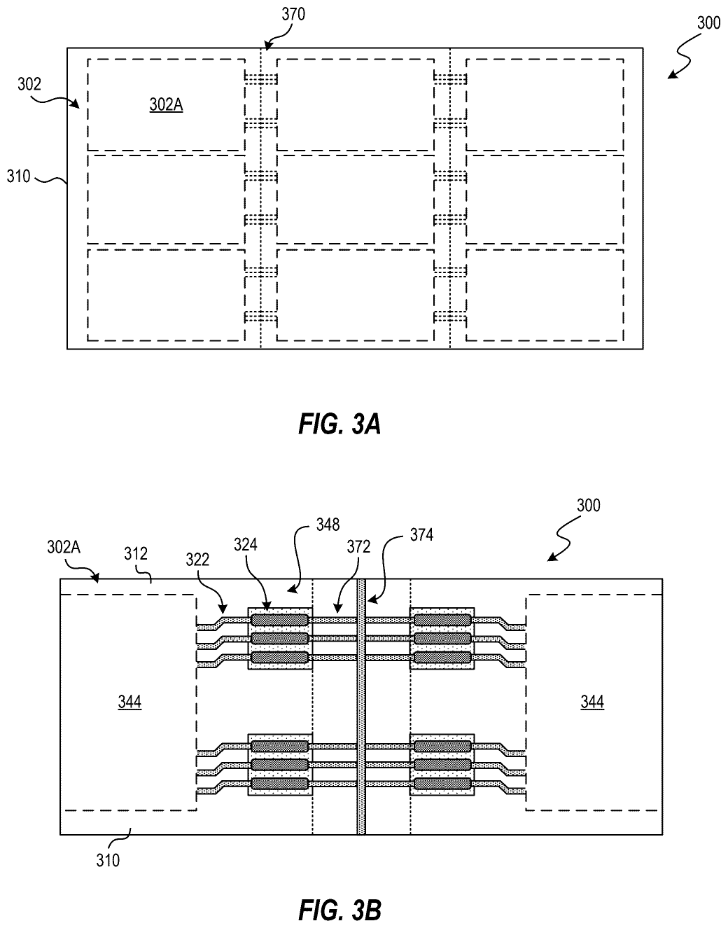

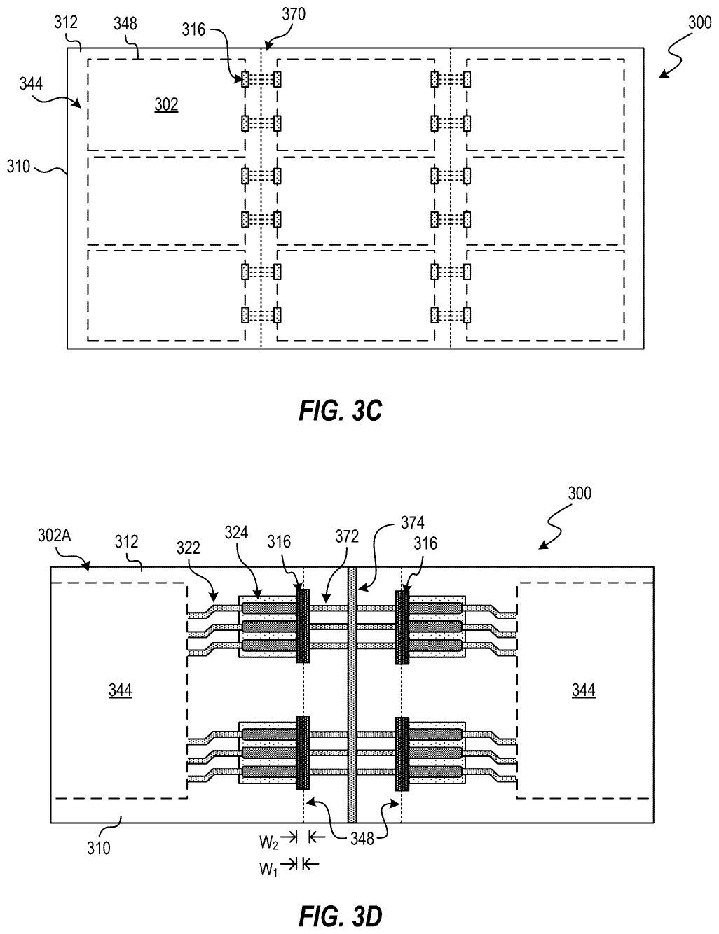

FIG. 2 is a flow diagram of a process 200 for manufacturing one or more stacked semiconductor devices in accordance with embodiments of the present technology. The process 200 is illustrated as a set of steps or blocks 202, 204, 206, 208, 210, 212, and 214 that can be implemented by one or more manufacturing apparatuses. All or a subset of one or more of these blocks 202, 204, 206, 208, 210, 212, and 214 can be executed in accordance with the discussion of FIGS. 3A-3D below. Further, the process 200 can be executed to form a stacked semiconductor device 100 of the type discussed above. Indeed, several of the blocks 202, 204, 206, 208, 210, 212, and 214 of the process 200 are described below with reference to the stacked semiconductor device 100 illustrated in FIGS. 1A-1C.

The process 200 begins at block 202 by forming one or more metallization structures on a semiconductor substrate. The semiconductor substrate can be a bulk interposer that includes a prepreg substrate, a silicon substrate, and/or any other suitable substrate. The metallization structures can include various metallization layers (e.g., traces, route lines, and/or the like), TSVs, external and/or internal bond pads, bond fingers, access pins, interposer bus lines, and/or the like. Further, the metallization layers formed at block 202 can be configured for use in one or more stacked semiconductor packages that are produced by the process 200. For example, the metallization layers can form bond fingers, route lines, external bond pads, and/or the like for one or more planned packages (sometimes referred to herein as “package regions”).

At block 204, the process 200 includes testing the metallization layers. The testing can help ensure that the metallization layers are properly formed and/or identify faulty metallization structures in the semiconductor substrate. For example, for each of the planned packages, the tests can check whether various signal route lines are functioning (e.g., intact, have losses within an allowed tolerance, and/or the like). The testing can be completed using one or more access pins and/or an interposer bus formed in block 202. In a specific, non-limiting example, the interposer bus can be coupled to bond fingers for multiple planned packages, allowing each of the planned packages to be tested through the interposer bus. However, the electrical connection between the bond fingers and the interposer bus can result in conductive structures at the edge of the planned packages during singulation (e.g., the conductive material in the bond fingers and/or traces coupled to the bond pads in the bond fingers). As discussed above, the conductive material, if not addressed can have deleterious effects on the resulting semiconductor packages.

Accordingly, at block 206, the process 200 includes cutting into an active surface (e.g., the front surface 112 of FIG. 1A) of the semiconductor substrate. More specifically, the process 200 at block 206 can cut into the active surface through the bond fingers (or other conductive material) at the edges of the planned packages. As a result, the cuts (sometimes also referred to herein as “stepped structures,” “trenches,” “clefts,” and/or the like) can decouple the bond fingers from the interposer substrate and/or be spaced physically apart from the edge of the planned packages. In various embodiments, as discussed above, the process 200 can form the cuts using a laser (e.g., via laser ablation, laser etching, and/or the like), a dicing saw, plasma (e.g., via plasma etching). As a result, the cuts can have a relatively small width (e.g., less than about 100 μm, about 50 μm, and/or any other suitable width). Further, as also discussed above with reference to FIGS. 1A-1C, the cuts can be formed to any suitable intermediate depth within the base substrate and/or have any suitable length. Purely by way of example, one or more of the cuts can be isolated to being adjacent to the bond fingers of a first planned package (e.g., having a length generally equal to an edge length of the bond fingers in the first planned package) while another cut can run the entire length of an edge of a second planned package.

At block 208, the process 200 includes stacking one or more dies over a central portion of each of the planned packages. The dies can include any suitable semiconductor dies (e.g., memory dies, logic dies, processing dies, and/or the like). Further, the dies can be stacked in an aligned stack and/or laterally offset (e.g., as illustrated in FIG. 1A). At block 210, the process 200 includes electrically coupling the die(s) in each of the planned packages to the active surface. In some embodiments, process 200 can electrically couple the dies to the active surface by forming one or more wire bonds (e.g., the wire bonds 142 of FIG. 1A), electrically coupling TSVs in the dies (e.g., via solder bonds, metal-metal bonds, hybrid bonds, and/or the like), and/or the like. In some embodiments, the process 200 can execute blocks 208 and 210 generally simultaneously (e.g., sometimes referred to collectively as “integrating” the dies with the active surface). For example, the dies can be alternatingly stacked and electrically coupled (via wire bonding, reflow processes, metal-metal bonds, and/or the like) to the active surface and/or underlying dies.

At block 212, the process 200 includes depositing a mold material (e.g., the mold material 150 of FIG. 1A) over the active surface to at least partially encapsulate the stacked dies and electrical connections and to fill the cuts formed at block 206. That is, the mold material can fill the space between the bond fingers (and/or other conductive structures) and the edge of the planned packages. As a result, the mold material can insulate the bond fingers (and/or other conductive structures) from exposure at the sidewalls of the semiconductor packages resulting from the process 200 (e.g., as illustrated in FIG. 1B).

At block 214, the process 200 includes singulating the semiconductor packages formed in the semiconductor substrate (e.g., singulating each of the planned packages). The singulation at block 214 can be completed using various semiconductor manufacturing processes, such as blade dicing, laser etching, plasma etching, stealth dicing, and/or any other suitable process.

Although the blocks 202, 204, 206, 208, 210, 212, and 214 of the process 200 are discussed and illustrated in a particular order, the process 200 illustrated in FIG. 2 is not so limited. In other embodiments, the process 200 can be performed in a different order. In these and other embodiments, any of the blocks 202, 204, 206, 208, 210, 212, and 214 of the process 200 can be performed before, during, and/or after any of the other blocks 202, 204, 206, 208, 210, 212, and 214 of the process 200. For example, all or a subset of blocks 208 and 210 can be executed before block 206 to stack and electrically couple the dies on the base substrate before forming the cuts in the active surface. In another example, blocks 204 and 206 can be executed after blocks 208 and 210, allowing the testing process to also test electrical connections to the stacked dies. Moreover, a person of ordinary skill in the relevant art will recognize that the illustrated process 200 can be altered and remain within these and other embodiments of the present technology. For example, one or more blocks 202, 204, 206, 208, 210, 212, and 214 of the process 200 illustrated in FIG. 2 can be omitted and/or repeated in various suitable processes. As a specific example, all or a subset of block 204 can be omitted such that the process 200 does not include testing the metallization layers (and/or dies). Still further, it will be understood that the process can be split between manufacturing apparatuses. Purely by way of example, a first apparatus can execute blocks 202, 204, and 206 to form a bulk interposer substrate that is sold, shipped, moved to another apparatus, and/or the like for the remainder of the process 200 (or any suitable subset thereof) to be executed.

FIGS. 3A-3D are partially schematic top views of a bulk interposer 300 at various stages of manufacturing in accordance with embodiments of the present technology. The stages of the manufacturing process illustrated in FIGS. 3A-3D can be generally similar to results from the process 200 discussed above with reference to FIG. 2. Accordingly, FIGS. 3A-3D are described below with frequent reference to FIG. 2.

For example, FIG. 3A illustrates the bulk interposer 300 (“interposer 300”) after metallization structures have been formed in a base substrate 310 of the interposer 300 (e.g., at block 202 of FIG. 2) and/or after stacking one or more dies in each of the package regions. As a result, the base substrate 310 can include various route lines, bonding features, and/or the like for each of a plurality of package regions 302 (illustrated schematically), as well as an interposer bus 370 that is coupled to each of the plurality of package regions 302.

For example, FIG. 3B illustrates the connection between a first package region 302A of FIG. 3A. As illustrated in FIG. 3B, the metallization structures in the first package region 302A can include route lines 322 and bond fingers 324 formed on an active surface of the base substrate 310. The bond fingers 324 provide a connection area for wire bonds and other conductive features in a resulting semiconductor package (e.g., the wire bonds 142 of FIG. 1A). In turn, the route lines 322 couple the bond fingers 324 (and anything coupled thereto) to metallization structures (e.g., TSVs, further route lines, and/or the like) in a die stacking area 344 of the first package region 302A, thereby forming route lines throughout the first package region 302A (and therefore the planned semiconductor package).

As further illustrated in FIG. 3B, the interposer bus 370 (sometimes also referred to herein as a “package bus”) can include one or more connection lines 372 coupled between the bond fingers 324 and a main bus line 374. The main bus line 374, in turn, can be coupled to one or more access pins (not shown), a controller circuit formed on the base substrate 310 (FIG. 3A), a processing circuit formed on the base substrate 310, and/or any other suitable component. As a result of the connections, the interposer bus 370 allows the connections in the first package region 302A (and/or any dies already integrated therewith) to be tested during manufacturing. The tests can help identify faulty connections, package regions that do not meet standards (e.g., and should not have dies stacked thereon and/or that should be addressed by further manufacturing processes), and/or otherwise identify issues in the package regions 302 (FIG. 3A).

However, the electrical connection between the interposer bus 370 and the metallization structures in the package regions 302 (FIG. 3A) requires conductive structures to be formed across planned peripheral edges (e.g., planned singulation lines) for the package regions 302. For example, as further illustrated in FIG. 3B, the bond fingers 324 can cross a planned peripheral edge 348 for the first package region 302A. As a result, similar to the discussion above, the bond fingers 324 would be exposed at the sidewall of a resulting semiconductor package when singulated along the planned peripheral edge 348. The exposure, in turn, could cause deleterious effects for the resulting semiconductor package. To address these shortcomings, as also discussed above, the manufacturing process can form one or more cuts along the planned peripheral edge 348.

FIGS. 3C and 3D illustrate the interposer 300 after a plurality of cuts 316 have been formed in the active surface 312 of the base substrate 310 (e.g., at block 206 of FIG. 2). As discussed above, the cuts 316 can be formed using a laser, a dicing saw, plasma exposure, and/or any other suitable method to create a trench in the active surface 312. Further, the cuts 316 can be formed along the planned peripheral edge 348 of each of the package regions 302. As a result, the cuts 316 can break a connection between the metallization structures in the package regions 302 and the interposer bus 370 and create space between the metallization structures and the planned peripheral edge 348.

For example, as best illustrated in the first package region 302A in FIG. 3D, the cuts 316 can intersect the bond fingers 324 along the planned peripheral edge 348. As a result, the cuts 316 can break the connection between the bond fingers 324 and the connection lines 372 (and the main bus line 374) of the interposer bus. Further, the portion of the cuts 316 that are within the footprint of the first package region 302A (e.g., to the left of the planned peripheral edge 348 in the illustrated view) can create a space between the bond fingers 324 and the planned peripheral edge 348. In turn, when the first package region 302A is singulated from the interposer 300, the portion of the cuts 316 that are within the footprint of the first package region 302A creates a space between the bond fingers 324 and the sidewall of the resulting package.

In the illustrated embodiments, the cuts 316 are isolated from each other (e.g., non-continuous) and are formed generally adjacent to the bond fingers 324. In various other embodiments, however, the cuts 316 can have different lengths, can be generally continuous along the active surface 312, and/or can be formed in various different locations. Purely by way of example, one or more of the cuts 316 can be continuous across the interposer. In another example, the cuts 316 can be formed adjacent to other conductive structures in the base substrate 310 (e.g., metallization layers. Such as the metallization layers 122 of FIG. 1A).

Further, in the illustrated embodiments, the cuts 316 are generally centered along the planned peripheral edges 348. As a result, as illustrated in FIG. 3D, the cuts 316 can have a second width W₂ while the portion of the cuts 316 that will remain after singulation can have a third width W₃ that is smaller than the second width W₂. The smaller third width W₃ can reduce the amount of material in the bond fingers 324 that is removed to space the bond fingers 324 apart from the planned peripheral edges 348 while preserving the insulative benefits of the space. As a result, the smaller third width W₃ can help maintain a size of the bond fingers 324 available for bonding (e.g., to wire bonds) within the planned package regions 302. It will be understood, however, that the cuts 316 can be formed with all (or generally all) of their width within the footprint of the planned package regions 302, thereby making the third width W₃ generally equal to the second width W₂. The relatively large third width W₃ can help ensure that sufficient space exists between the bond fingers 324 and the planned peripheral edges 348 to reduce (or eliminate) migration, corrosion, and/or other deleterious effects at the sidewalls of resulting semiconductor packages. Purely by way of example, the relatively large third width W₃ can provide additional tolerance for drift and/or errors in the singulation process away from the planned peripheral edges 348. In various embodiments, as discussed above, the second width W₂ can be between about 100 μm and about 50 μm, between about 70 μm and about 10 μm, and/or about 50 μm.

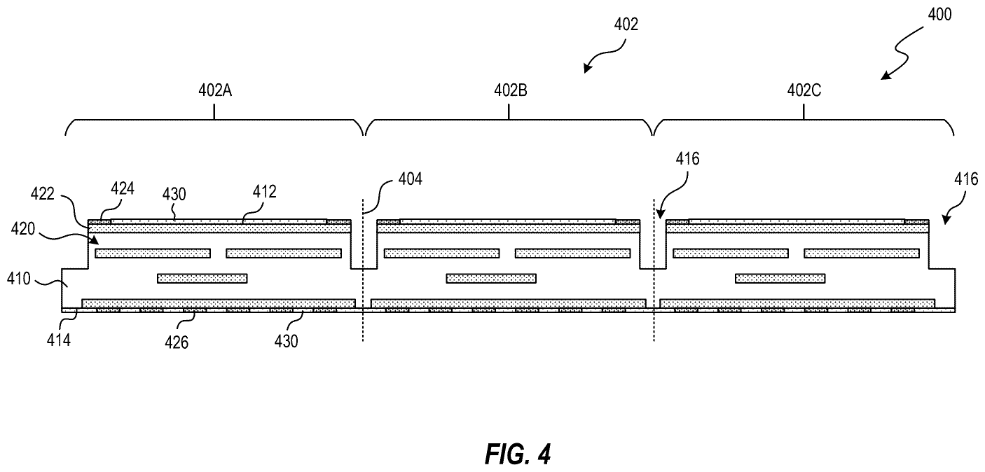

FIG. 4 is a partially schematic cross-sectional view of an interposer 400 configured in accordance with embodiments of the present technology. The interposer 400 can be generally similar to the interposer 300 resulting from the manufacturing process discussed above with reference to FIGS. 3A-3D and/or an interposer resulting from a blocks 202-206 the process 200 discussed above with reference to FIG. 2.

In the illustrated embodiment, the interposer 400 includes a base substrate 410 that includes an active surface 412 and a back surface 414 opposite the active surface 412 and is divided into a plurality of package regions 402 (three illustrated, referred to individually as a first package region 402A, a second package region 402B, and a third package region 402C). The base substrate 410 (sometimes also referred to herein as a “core substrate”) can include any suitable semiconductor material, such as a prepreg substrate, silicon, various other organic materials, and/or various suitable inorganic materials. Further, as illustrated in FIG. 4, each of the package regions 402 includes various metallization structures 420 formed in the base substrate. For example, as illustrated with respect to the first package region 402A, the metallization structures 420 the package regions 402 can include metallization layers 422 (e.g., metal route lines, traces, and/or the like) formed throughout the base substrate 410; bond fingers 424 formed on the active surface 412 of the base substrate 410; and external package bond sites 426 formed on the back surface 414 of the base substrate 410.

The interposer 400 also includes a dielectric layer 430 formed around the base substrate 410. The dielectric layer can be formed on both the active surface 412 and the back surface 414 of the base substrate 410. Further, the dielectric layer 430 can be formed on around the metallization structures 420 with openings for the bond fingers 424, the external package bond sites 426, and/or any other suitable structures. Accordingly, the dielectric layer 430 can insulate and/or protect the base substrate 410 and/or various components of the metallization structures 420.

As further illustrated in FIG. 4, the interposer 400 also includes trenches 416 formed in the active surface 412 of the base substrate 410. The trenches 416 are positioned at the peripheral edges of the package regions 402, thereby creating a space between the bond fingers 424 and planned singulation lines 404 between the package regions 402 and/or peripheral edges of the base substrate 410. Said another way, adjacent package regions 402 are separated by the trenches 416, and/or the trenches 416 create a stepped structure along a peripheral edge of the base substrate 410. Similar to the discussion above, the space created by the trenches 416 can create a space between the bond fingers 424 and sidewalls of semiconductor packages that result from each of the package regions 402A.

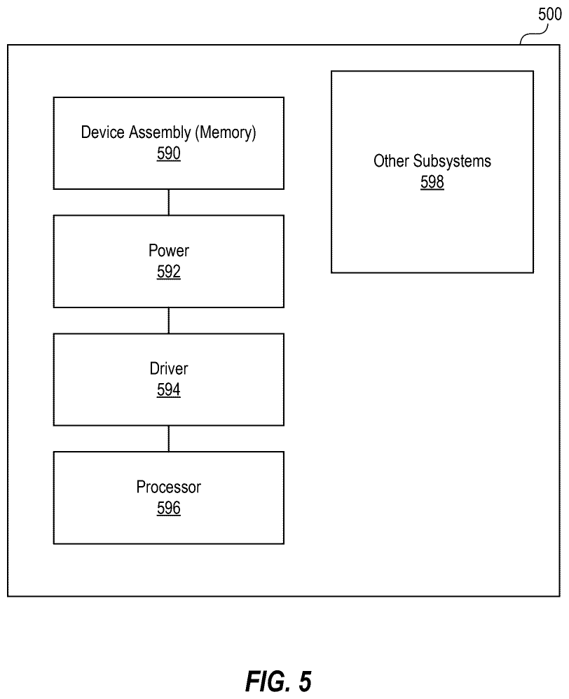

FIG. 5 is a schematic view of a system that includes stacked semiconductor devices configured in accordance with embodiments of the present technology. That is, the stacked semiconductor packages discussed above can be incorporated into any of a myriad of larger and/or more complex systems, a representative example of which is system 500 shown schematically in FIG. 5. The system 500 can include a memory 590 (e.g., SRAM, DRAM, flash, and/or other memory devices), a power supply 592, a drive 594, a processor 596, and/or other subsystems or components 598. Semiconductor packages of the type discussed above with reference to FIGS. 1A-1C and/or resulting from the processes discussed above with respect to FIGS. 2-3D can be included in any of the elements shown in FIG. 5. Purely by way of example, the stacked semiconductor packages discussed with reference to FIGS. 1A-1C can be deployed in the memory 590 (e.g., in a managed NAND for us in various consumer electronics, automotive electronics, and the like; an SSD package; and/or any other suitable memory device).

The resulting system 500 can be configured to perform any of a wide variety of suitable computing, processing, storage, sensing, imaging, and/or other functions. Accordingly, representative examples of the system 500 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 500 include lights, cameras, vehicles, etc. With regard to these and other examples, the system 500 can be housed in a single unit or distributed over multiple interconnected units, e.g., through a communication network. The components of the system 500 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately”, “about,” and “generally” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor package, comprising:
a base substrate having a central portion and a peripheral portion at least partially surrounding the central portion, wherein the base substrate comprises:
an active surface, wherein the active surface includes one or more cuts into the peripheral portion;
a back surface opposite the active surface; and
a plurality of bond pads carried by the active surface over the peripheral portion, each of the plurality of bond pads abutting one of the one or more cuts;
a stack of dies carried by the active surface over the central portion, wherein each die in the stack of dies is electrically coupled to at least one bond pad from the plurality of bond pads; and
a mold material deposited over the active surface and at least partially encapsulating the stack of dies, wherein the mold material fills each of the one or more cuts in the active surface.

2. The stacked semiconductor package of claim 1, wherein the base substrate has a footprint with a peripheral edge, and wherein the one or more cuts space each of the plurality of bond pads apart from the peripheral edge of the footprint.

3. The stacked semiconductor package of claim 2, wherein a portion the mold material is positioned between each of the plurality of bond pads and the peripheral edge.

4. The stacked semiconductor package of claim 1, wherein the base substrate has a first depth between the active surface and the back surface, and wherein each of the one or more cuts has a second depth smaller than the first depth.

5. The stacked semiconductor package of claim 1, wherein each of the one or more cuts has a width less than or equal to 25 micrometers.

6. The stacked semiconductor package of claim 1, wherein subsets of two or more of the plurality of bond pads are grouped into bond fingers, and wherein each of the one or more cuts is isolated to a corresponding one of the bond fingers.

7. The stacked semiconductor package of claim 1, wherein each of the one or more cuts traces an entire peripheral edge of the active surface.

8. A method for forming a plurality of stacked semiconductor packages on a base substrate having a plurality of die stack areas, the method comprising:
forming one or more metallization layers in the base substrate, wherein the one or more metallization layers comprise a plurality of bonding structures on an active surface of the base substrate, wherein each of the plurality of bonding structures is adjacent to a corresponding die stack area from a plurality of die stack areas;
forming one or more cuts in the active surface of the base substrate, wherein each of the one or more cuts passes through at least one bonding structure from the plurality of bonding structures;
for each individual die stack area from the plurality of die stack areas:
stacking one or more dies on the base substrate over the individual die stack area; and
electrically coupling each of the one or more dies to one or more of the plurality of bonding structures adjacent to the individual die stack area; and
depositing a mold material over the active surface to at least partially encase each of the one or more dies and fill each of the one or more cuts.

9. The method of claim 8, wherein each individual stacked semiconductor package from the plurality of stacked semiconductor packages has a peripheral edge, and wherein each of the one or more cuts traces at least a portion of the peripheral edge of at least one corresponding individual stacked semiconductor package.

10. The method of claim 8, wherein forming the one or more cuts in the active surface of the base substrate comprises directing a laser onto the active surface of the base substrate.

11. The method of claim 8, wherein forming the one or more cuts in the active surface of the base substrate comprises dicing the base substrate to an intermediate depth of the base substrate through the active surface.

12. The method of claim 8, wherein:
the active surface of the base substrate includes a plurality of bond fingers each having two or more of the bonding structures, wherein each of the plurality of bond fingers has an edge length; and
the one or more cuts includes a plurality of cuts, wherein each of the plurality of cuts is adjacent to a corresponding bond finger, and wherein each of the plurality of cuts has a length approximately equal to the edge length of the corresponding bond finger.

13. The method of claim 8, further comprising singulating individual stacked semiconductor packages from along planned singulation lines, wherein each of the planned singulation lines passes at least partially through at least one of the one or more cuts in the active surface.

14. The method of claim 8, wherein forming the one or more cuts in the active surface of the base substrate comprises forming the one or more cuts with a width less than or equal to 50 micrometers.

15. A semiconductor substrate, comprising:
a core substrate having a front surface and a back surface opposite the front surface, wherein the front surface includes:
a plurality of package regions; and
for each individual package region of the plurality of package regions, one or more trenches into the front surface along a peripheralmost edge of the individual package region; and
for each individual package region of the plurality of package regions, one or more bond fingers formed on the front surface, wherein each individual bond finger is positioned adjacent to a corresponding individual trench from the one or more trenches.

16. The semiconductor substrate of claim 15, further comprising an interposer bus formed on the front surface adjacent to a subset of the plurality of package regions, wherein the interposer bus includes a plurality of connection lines, wherein each individual connection line is spaced apart from a corresponding bond finger in one of the individual package regions by a corresponding trench in the front surface.

17. The semiconductor substrate of claim 15, wherein:
adjacent package regions in the plurality of package regions are separated by a planned singulation line; and
for each individual package region of the adjacent package regions, each individual bond finger is spaced apart from the planned singulation line by at least a portion of the corresponding individual trench.

18. The semiconductor substrate of claim 15, wherein a distance between the front surface and the back surface is a first distance, wherein each of the one or more trenches extends a second distance into the core substrate toward the back surface, wherein the second distance is less than the first distance.

19. The semiconductor substrate of claim 15, wherein the one or more trenches includes a plurality of trenches, and wherein each individual trench in the plurality of trenches is physically isolated from other trenches in the plurality of trenches.

20. The semiconductor substrate of claim 15, wherein at least one of the one or more trenches has a length generally equal to an edge length of a corresponding bond finger from the one or more bond fingers.
